(19) United States
(12) Patent Application Publication
(10) Pub. No.: US 2026/0162731 A1
(43) Pub. Date: Jun. 11, 2026

(54) MEMORY DEVICE AND OPERATION METHOD THEREOF

(71) Applicant: Samsung Electronics Co., Ltd., Suwon-si (KR)

(72) Inventors: Na-Young CHOI, Suwon-si (KR); Ji-Sang LEE, Suwon-si (KR); Yonghyuk CHOI, Suwon-si (KR)

(21) Appl. No.: 19/405,898

(22) Filed: Dec. 2, 2025

(30) Foreign Application Priority Data
Dec. 6, 2024 (KR) 10-2024-0180618

(51) Int. Cl. G11C 16/26; G11C 16/24; G11C 16/30

(52) U.S. Cl. CPC G11C 16/26; G11C 16/24; G11C 16/30

(57) ABSTRACT

An example memory device includes a memory block including a first sub-block, including first memory cells connected to word lines, first bit lines, and a first common source line, and a second sub-block, including second memory cells connected to the word lines, second bit lines, and a second common source line, a page buffer circuit including first page buffers connected to the first bit lines and second page buffers connected to the second bit lines, and a control logic configured to, during a sensing operation for a plurality of memory cells of the first sub-block and the second sub-block, individually control a first voltage applied to the first common source line and a second voltage applied to the second common source line, the plurality of memory cells connected to a word line among the plurality of word lines.

### CROSS-REFERENCE TO RELATED APPLICATION

This application claims the benefit of Korean Patent Application No. 10-2024-0180618, filed on December 6, 2024, in the Korean Intellectual Property Office, the disclosure of which is incorporated herein by reference in its entirety.

### BACKGROUND

A memory device includes a memory block, and the memory block includes a plurality of memory cells to store data. The data corresponds to a threshold voltage state of a memory cell, and the threshold voltage state may be sensed using a current flowing through a bit line according to a voltage applied to a word line. To enhance the performance of the memory device and increase the speed of data access, a faster and more efficient sensing manner is desired.

### SUMMARY

The present disclosure relates to a memory device, which performs an efficient sensing operation, and an operation method thereof.

Example implementations are not limited to the technical goals described above, and other technical goals may be inferred from the example implementations below.

In general, according to some aspects, a memory device includes a memory block including a first sub-block and a second sub-block, wherein the first sub-block includes a plurality of first memory cells, the plurality of first memory cells are connected to a plurality of word lines, a plurality of first bit lines, and a first common source line, and a second sub-block includes a plurality of second memory cells, and the plurality of second memory cells are connected to the plurality of word lines, a plurality of second bit lines and a second common source line, a page buffer circuit including a plurality of first page buffers and a plurality of second page buffers, wherein the plurality of first page buffers are connected to the plurality of first bit lines and the plurality of second page buffers are connected to the plurality of second bit lines, and a control logic configured to, during a sensing operation for a plurality of memory cells of the first sub-block and the second sub-block, individually control a first voltage applied to the first common source line and a second voltage applied to the second common source line the plurality of memory cells are connected to a word line among the plurality of word lines.

In general, according to some aspects, an operation method of a memory device, including a memory block including a first sub-block and a second sub-block, the first sub-block including a plurality of first memory cells, the plurality of first memory cells being connected to a plurality of word lines, a plurality of first bit lines, and a first common source line, the second sub-block including a plurality of second memory cells, the plurality of second memory cells being connected to the plurality of word lines, a plurality of second bit lines, and a second common source line, includes applying, during a precharge operation, a first precharge voltage to the plurality of first bit lines and a second precharge voltage to the plurality of second bit lines, and applying a first voltage to the first common source line and a second voltage to the second common source line, the first voltage being different from the second voltage, and identifying, based on a target voltage being applied to a word line among the plurality of word lines and, during a detection operation, a plurality of first threshold voltage states of a first plurality of memory cells of the first sub-block connected to the word line through the plurality of first bit lines, and identifying a plurality of second threshold voltage states of a second plurality of memory cells of the second sub-block connected to the word line through the plurality of second bit lines.

In general, according to some aspects, a memory device includes a memory block including a plurality of sub-blocks, each sub-block of the plurality of sub-blocks being connected to a common source line of a plurality of common source lines separated from each other, a page buffer circuit including a plurality of page buffers, each page buffer of the plurality of page buffers being connected to a sub-block of the plurality of sub-blocks through a respective bit line and configured to apply a precharge voltage to the respective bit line based on a bit line control voltage, a source line driver configured to apply a separate voltage to each common source line of the plurality of common source lines, and a control logic configured to control, during a sensing operation for the plurality of sub-blocks, the source line driver to adjust the separate voltage applied to each common source line of the plurality of common source lines.

Details of example implementations are included in the detailed description and drawings.

### BRIEF DESCRIPTION OF THE DRAWINGS

These and/or other aspects, features, and advantages of the present disclosure will become apparent and more readily appreciated from the following description of example implementations, taken in conjunction with the accompanying drawings.

FIG. 1 is a block diagram for illustrating an example of a memory device and an example of a storage device.

FIG. 2 is a diagram for illustrating an example of a memory device.

FIG. 3 is a diagram for illustrating an example of a structure of a memory block.

FIG. 4 is a diagram for illustrating an example of a string and an example of a page buffer.

FIG. 5 is a diagram for illustrating an example of a sensing operation.

FIG. 6 is a diagram for illustrating an example of a threshold voltage distribution of memory cells.

FIG. 7 is a diagram for illustrating an example of a threshold voltage distribution of memory cells and an example of a method of determining an optimum voltage.

FIG. 8 is a diagram for illustrating an example of an operation method of a memory device.

### DETAILED DESCRIPTION

Terms used in example implementations are selected from currently widely used general terms when possible while considering the functions in the present disclosure. However, the terms may vary depending on the intention of a person skilled in the art, precedents, the emergence of new technology, and the like. Further, in certain cases, there are also terms arbitrarily selected by the applicant, and in these cases, the meaning will be described in detail in the corresponding descriptions. Therefore, the terms used in the present disclosure are not to be construed simply as its designation but based on the meaning of the term and the overall context of the present disclosure.

Throughout the specification, when a part is described as "comprising or including" a component, it does not exclude another component but may further include another component unless otherwise stated. Further, terms such as "... unit," "... part," and "... module" described in the specification mean a unit that processes at least one function or operation, which may be implemented as hardware, software, or a combination thereof.

Hereinafter, example implementations of the present disclosure will be described in detail with reference to the accompanying drawings so that those of ordinary skill in the art to which the present disclosure pertains may easily implement the example implementations. However, the present disclosure may be implemented in many different forms and is not limited to the example implementations described herein.

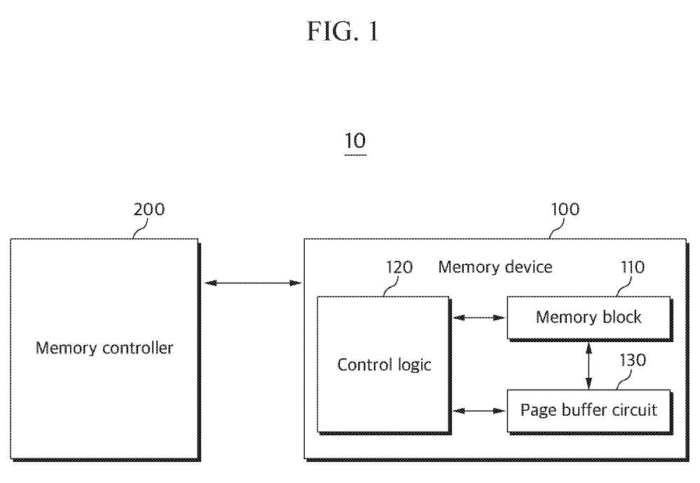

FIG. 1 is a block diagram for illustrating an example of a memory device and an example of a storage device.

Referring to FIG. 1, a storage device 10 may include a memory device 100 and a memory controller 200. In some implementations, the memory device 100 may be implemented as various electronic devices that store data. For example, the memory device 100 may be implemented in the form of NAND flash memory, vertical NAND flash memory, NOR flash memory, resistive random access memory (RRAM), phase-change memory (PRAM), magnetoresistive random access memory (MRAM), ferroelectric random access memory (FRAM), spin transfer torque random access memory (STT-RAM), or the like. The memory device 100 may be implemented in a three-dimensional array structure. However, this is merely an example implementation, and the memory device 100 may be modified and implemented in various forms not enumerated.

The memory controller 200 may control the memory device 100. In some implementations, the memory controller 200 may transmit a command for controlling the memory device 100 to the memory device 100. When the command is received, the memory device 100 may perform an operation corresponding to the command. In some implementations, the memory controller 200 may transmit an address indicating a specific storage area of the memory device 100 together with the command to the memory device 100. When the command and the address are received, the memory device 100 may perform the operation corresponding to the command for a storage area corresponding to the address.

For example, the command may include at least one of various types of commands such as a program command to control performing a program operation of storing data in a memory block 110 and a read command to control performing a sensing operation of sensing data stored in the memory block 110. The address may indicate the specific storage area of the memory device 100. For example, a type of the address may include at least one of a block address indicating a specific memory block (or sub-block) among a plurality of memory blocks, a row address indicating a specific row (for example, a word line or a page), and a column address indicating a specific column (for example, a bit line or a string).

The memory device 100 may include at least one memory block 110, a control logic 120, and a page buffer circuit 130. The memory block 110 may include a plurality of memory cells. The memory cell may include an element that stores data. The memory cell may store one or more bits. For example, the memory cell of a single-level cell (SLC) type may store 1 bit, the memory cell of a multi-level cell (MLC) type may store 2 bits, and the memory cell of a triple-level cell (TLC) type may store 3 bits. However, this is merely an example implementation, and the type of the memory cell may be modified and implemented in various types such as a quad-level cell (QLC) type.

The control logic 120 may control overall operations of the memory device 100. The control logic 120 may process the command or the address or perform a computation. The control logic 120 may transmit a control signal required for each operation to another component of the memory device 100. The control logic 120 may control a level of a voltage regarding the operation.

The page buffer circuit 130 may be connected to the memory block 110. The page buffer circuit 130 may sense data stored in the memory block 110 during the sensing operation. The page buffer circuit 130 may transfer data to be stored to the memory block 110 during the program operation.

In some implementations, the memory block 110 may include a plurality of sub-blocks.

Each of the plurality of sub-blocks may be connected to one of a plurality of common source lines separated from each other. Each of the plurality of sub-blocks may be connected to one of a plurality of bit lines separated from each other. The control logic 120 may individually control a level of a voltage applied to each of a first common source line and a second common source line during the sensing operation for the plurality of sub-blocks. In other words, the memory device 100 may sense data stored in the plurality of sub-blocks by controlling a voltage difference between a bit line and a common source line independently for each sub-block. Hereinafter, example implementations of the present disclosure are described in more detail.

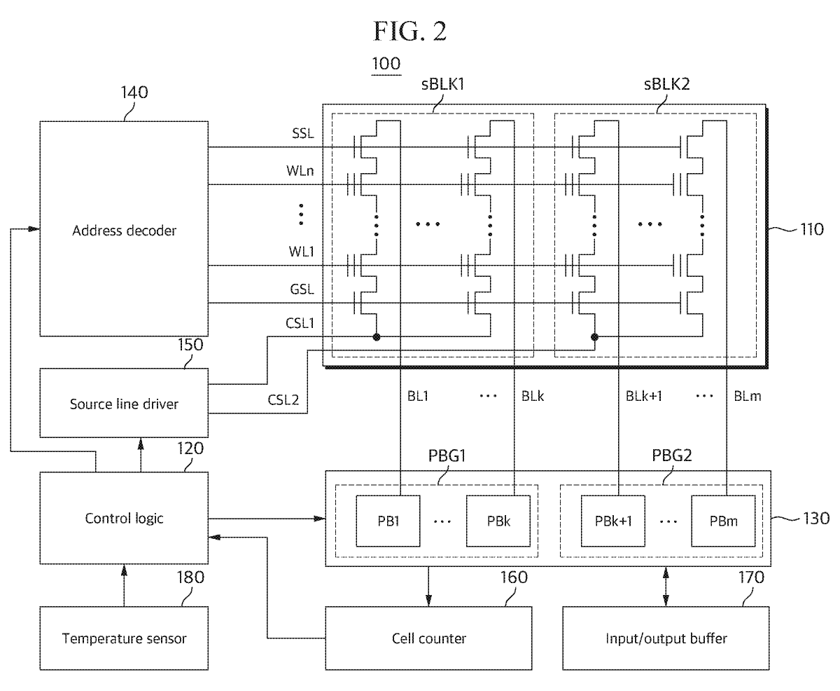

FIG. 2 is a diagram for illustrating an example of a memory device.

Referring to FIG. 2, the memory device 100 according to example implementations may include at least one memory block 110, the control logic 120, and the page buffer circuit 130.

The memory block 110 may include a plurality of sub-blocks sBLK1 and sBLK2. For example, the memory block 110 may include a first sub-block sBLK1 and a second sub-block sBLK2. The first sub-block sBLK1 may include a plurality of memory cells connected to a plurality of word lines WL1 to WLn, a plurality of first bit lines BL1 to BLk, and a first common source line CSL1. The second sub-block sBLK2 may include a plurality of memory cells connected to the plurality of word lines WL1 to WLn, a plurality of second bit lines BLk+1 to BLm, and a second common source line CSL2. In some implementations, the number of the memory block 110 and the number of the plurality of sub-blocks sBLK1 and sBLK2 may be modified and implemented in various manners, differently from FIG. 2.

One end of the plurality of sub-blocks sBLK1 and sBLK2 may be connected to one of a plurality of common source lines CSL1 and CSL2 separated from each other. For example, one end of the first sub-block sBLK1 may be connected to the first common source line CSL1, and one end of the second sub-block sBLK2 may be connected to the second common source line CSL2. The plurality of common source lines CSL1 and CSL2 may be electrically separated from each other.

Another end of the plurality of sub-blocks sBLK1 and sBLK2 may be connected to one of a plurality of bit lines BL1 to BLm separated from each other. For example, another end of the first sub-block sBLK1 may be connected to the plurality of first bit lines BL1 to BLk, and another end of the second sub-block sBLK2 may be connected to the plurality of second bit lines BLk+1 to BLm. The plurality of bit lines BL1 to BLm may be electrically separated from each other.

The plurality of sub-blocks sBLK1 and sBLK2 may be connected to the plurality of word lines WL1 to WLn and a plurality of special word lines SSL and GSL. In other words, the plurality of sub-blocks sBLK1 and sBLK2 may share identical word lines and special word lines with each other. Meanwhile, a plurality of strings included in a single sub-block among the plurality of sub-blocks sBLK1 and sBLK2 may share an identical common source line.

Each of the plurality of sub-blocks sBLK1 and sBLK2 may include a plurality of strings. One end of each string may be connected to one corresponding bit line among the plurality of bit lines BL1 to BLm, and another end of each string may be connected to a corresponding common source line among the plurality of common source lines CSL1 and CSL2. Each string may include a plurality of memory cells connected individually to the plurality of word lines WL1 to WLn. Each string may include a selection transistor connected to each of both ends of the plurality of memory cells.

For example, the first sub-block sBLK1 may include strings of first to k-th columns. One end of each of the strings of the first to k-th columns may be connected individually to a corresponding bit line (for example, one of the bit lines BL1 to BLk of the first to k-th columns), and another end of each of the strings of the first to k-th columns may be connected in common to the first common source line CSL1. Each of the strings of the first to k-th columns may include a plurality of memory cells connected individually to the plurality of word lines WL1 to WLn and selection transistors connected to both ends of the plurality of memory cells.

For example, the second sub-block sBLK2 may include strings of k+1-th to m-th columns. One end of each of the strings of the k+1-th to m-th columns may be connected individually to a corresponding bit line (for example, one of the bit lines BLk+1 to BLm of the k+1-th to m-th columns), and another end of each of the strings of the k+1-th to m-th columns may be connected in common to the second common source line CSL2. Each of the strings of the k+1-th to m-th columns may include a plurality of memory cells connected individually to the plurality of word lines WL1 to WLn and selection transistors connected to both ends of the plurality of memory cells.

The control logic 120 may control operations of other components within the memory device 100 through various control signals.

In some implementations, the control logic 120 may control the page buffer circuit 130 so that data stored in the memory block 110 is sensed and temporarily stored in the page buffer circuit 130 during a sensing operation. The control logic 120 may control the page buffer circuit 130 to transfer the data stored temporarily in the page buffer circuit 130 to the memory block 110 during a program operation.

The control logic 120 may individually control levels of voltages applied to the plurality of common source lines CSL1 and CSL2 during the sensing operation. For example, the control logic 120 may control a level of a voltage applied to the first common source line CSL1 and a level of a voltage applied to the second common source line CSL2 to be identical or different from each other.

In some implementations, the level of the voltage applied to the first common source line CSL1 may be different from the level of the voltage applied to the second common source line CSL2.

In some implementations, a voltage of a first polarity may be applied to the first common source line CSL1, and a voltage of a second polarity or a non-polar voltage may be applied to the second common source line CSL2. For example, the first polarity may be (+) or (-). The second polarity may be a polarity different from the first polarity. For example, when the first polarity is (+), the second polarity may be (-). The non-polar voltage may be a voltage having no polarity, and for example, a voltage of 0 volt (V) may be non-polar. In some implementations, a difference between the level of the voltage applied to the first common source line CSL1 and the level of the voltage applied to the second common source line CSL2 may be 0.4 V. For example, the level of the voltage applied to the first common source line CSL1 may be 0 V, and the level of the voltage applied to the second common source line CSL2 may be 0.4 V. For another example, the level of the voltage applied to the first common source line CSL1 may be -0.2 V, and the level of the voltage applied to the second common source line CSL2 may be 0.2 V. Meanwhile, this is merely an example implementation, and the difference between the level of the voltage applied to the first common source line CSL1 and the level of the voltage applied to the second common source line CSL2 may be modified and implemented in various manners.

In some implementations, the level of the voltage applied to the first common source line CSL1 may be less than a level of a precharge voltage applied to the plurality of first bit lines BL1 to BLk. The level of the voltage applied to the second common source line CSL2 may be less than a level of a precharge voltage applied to the plurality of second bit lines BLk+1 to BLm.

In some implementations, the level of the precharge voltage applied to the plurality of first bit lines BL1 to BLk may be identical to the level of the precharge voltage applied to the plurality of second bit lines BLk+1 to BLm.

In some implementations, the sensing operation may include a precharge operation for setting an initial state and a detection operation of sensing (or identifying) data of a memory cell. In some implementations, the sensing operation may include at least one of a first sensing operation of sensing data to find an optimum voltage level and a second sensing operation of finally sensing data. For example, each of the first sensing operation and the second sensing operation may include the precharge operation and the detection operation. The first sensing operation may be referred to as a pre-sensing operation, and the second sensing operation may be referred to as a main sensing operation.

The page buffer circuit 130 may include a plurality of page buffers PB1 to PBm. The plurality of page buffers PB1 to PBm may be connected individually to one of the plurality of sub-blocks sBLK1 and sBLK2 through a corresponding bit line among the plurality of bit lines BL1 to BLm. The plurality of page buffers PB1 to PBm may be sorted based on a connected sub-block. For example, the plurality of page buffers PB1 to PBm may be sorted into a plurality of first page buffers PBG1 connected to the first sub-block sBLK1 and a plurality of second page buffers PBG2 connected to the second sub-block sBLK2.

For example, the plurality of first page buffers PBG1 may include page buffers PB1 to PBk of the first to k-th columns. The page buffers PB1 to PBk of the first to k-th columns may be connected to the strings of the first to k-th columns of the first sub-block sBLK1 through a corresponding bit line (for example, one of the bit lines BL1 to BLk of the first to k-th columns).

For example, the plurality of second page buffers PBG2 may include page buffers PBk+1 to PBm of the k+1-th to m-th columns. The page buffers PBk+1 to PBm of the k+1-th to m-th columns may be connected to the strings of the k+1-th to m-th columns of the second sub-block sBLK2 through a corresponding bit line (for example, one of the bit lines BLk+1 to BLm of the k+1-th to m-th columns).

The plurality of page buffers PB1 to PBm may transfer a precharge voltage to the plurality of bit lines BL1 to BLm during the sensing operation. In some implementations, the plurality of page buffers PB1 to PBm may apply the precharge voltage to a corresponding bit line among the plurality of bit lines BL1 to BLm in response to a bit line control voltage.

The plurality of page buffers PB1 to PBm may sense data corresponding to a voltage or a current detected through the plurality of bit lines BL1 to BLm. The page buffer circuit 130 may store the sensed data. The page buffer circuit 130 may transfer the stored data to an input/output (I/O) buffer 170.

The memory device 100 according to some implementations may further include at least one of an address decoder 140, a source line driver 150, a cell counter 160, the input/output buffer 170, and a temperature sensor 180. In some implementations, the memory device 100 may further include a voltage generator to generate various operating voltages. Meanwhile, the remaining components excluding the memory block 110 from the memory device 100 may be referred to as a peripheral circuit.

The address decoder 140 may select one of a plurality of memory blocks according to a control signal (for example, an address) of the control logic 120 and apply a corresponding voltage to a selected memory block. For example, a case is assumed, in which the memory block 110 is selected as an operation target of the sensing operation according to the address and one of the plurality of word lines WL1 to WLn connected to the memory block 110 is selected. Here, a word line that is selected may be referred to as a selected word line, and a word line that is not selected may be referred to as an unselected word line. In addition, a memory cell connected to the selected word line may be referred to as a selected memory cell, and a memory cell connected to the unselected word line may be referred to as an unselected memory cell. In this case, the address decoder 140 may apply a target voltage for sensing a threshold voltage of the selected memory cell to the selected word line and apply a pass voltage for turning on the unselected memory cell to the unselected word line. Further, the address decoder 140 may apply a turn-on voltage for turning on a selection transistor to the plurality of special word lines SSL and GSL connected to the memory block 110.

The source line driver 150 may apply an individual voltage to each of the plurality of common source lines CSL1 and CSL2. In other words, the source line driver 150 may adjust a voltage of each of the plurality of common source lines CSL1 and CSL2 independently. Accordingly, a current flowing through each string for each sub-block sBLK1 and sBLK2 may be adjusted independently.

In some implementations, the source line driver 150 may include a first driver connected to the first common source line CSL1 to apply voltage and a second driver connected to the second common source line CSL2 to apply voltage. Meanwhile, the source line driver 150 may be modified to be implemented separately from the control logic 120 or included within the control logic 120.

In some implementations, the control logic 120 may perform the sensing operation simultaneously for the plurality of sub-blocks sBLK1 and sBLK2 included in the memory block 110. The control logic 120 may control the source line driver 150 to individually adjust a level of a voltage applied to each of the plurality of common source lines CSL1 and CSL2 through a control signal during the sensing operation for the plurality of sub-blocks sBLK1 and sBLK2. For example, the control logic 120 may control the source line driver 150 to differently adjust the level of the voltage applied to each of the plurality of common source lines CSL1 and CSL2.

In some implementations, the control logic 120 may control the source line driver 150 so that the level of the voltage applied to each of the plurality of common source lines CSL1 and CSL2 is less than a level of a precharge voltage applied to a corresponding bit line. The precharge voltage may be a voltage applied to a bit line to perform the sensing operation. For example, the precharge voltage may be a voltage applied to a bit line during the precharge operation of the sensing operation.

The cell counter 160 may count the number of memory cells having a threshold voltage in a specific range (or specific interval). In some implementations, the cell counter 160 may count the number of memory cells having a threshold voltage in the specific range by processing data stored in the page buffer circuit 130.

The input/output buffer 170 may receive data stored in the page buffer circuit 130 to output to the outside during the sensing operation. The input/output buffer 170 may transfer data received from outside to the page buffer circuit 130 during the program operation.

The temperature sensor 180 may identify a temperature. For example, the temperature sensor 180 may periodically identify an internal temperature of the memory device 100. The temperature sensor 180 may be implemented as temperature sensors using various manners such as a resistance temperature detector and a thermocouple. The temperature sensor 180 may transfer the temperature to the control logic 120.

In some implementations, the control logic 120 may correct a level of a voltage applied to each of the first common source line CSL1 and the second common source line CSL2 based on the temperature.

For example, the control logic 120 may add a first offset level corresponding to the temperature to a reference level of the voltage applied to the first common source line CSL1. For example, the control logic 120 may add a second offset level corresponding to the temperature to a reference level of the voltage applied to the second common source line CSL2. Here, the first offset level and the second offset level may refer to a change in voltage level based on temperature. In some implementations, the first offset level and the second offset level may be set to an identical value at the same temperature. In another example implementation, the first offset level and the second offset level may be set to different values at the same temperature. In some implementations, a correction table including the first offset level and the second offset level corresponding to temperature may be stored in the control logic 120 in advance.

In some implementations, the control logic 120 may, as the temperature rises, correct a level of the voltage applied to the first common source line CSL1 to increase and correct a level of the voltage applied to the second common source line CSL2 to increase. Compared to before the correction, a level of current flowing within a string may decrease.

In another example implementation, the control logic 120 may, as the temperature rises, correct a level of the voltage applied to the first common source line CSL1 to decrease and correct a level of the voltage applied to the second common source line CSL2 to decrease. Compared to before the correction, a level of current flowing within a string may increase.

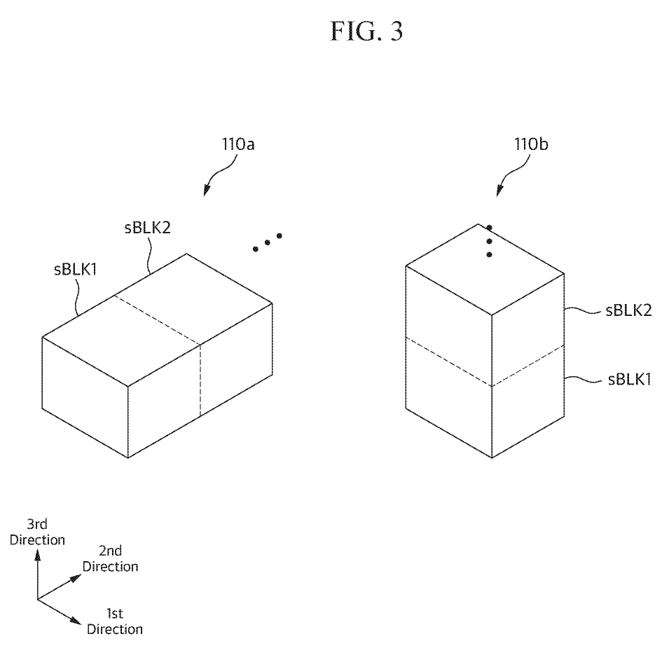

FIG. 3 is a diagram for illustrating an example of a structure of a memory block.

Referring to FIGS. 2 and 3, the memory block 110 according to some implementations may be implemented as one of a first-type memory block 110a or a second-type memory block 110b.

The first-type memory block 110a may include the plurality of sub-blocks sBLK1 and sBLK2 arranged in a first direction or a second direction. In this case, the second sub-block sBLK2 may be disposed to be spaced apart from the first sub-block sBLK1 in the first direction or the second direction. For example, the first direction may be a first horizontal direction (or X-axis direction), and the second direction may be a second horizontal direction (or Y-axis direction). The first direction may be perpendicular to the second direction, but is not limited thereto, and may be modified in various manners.

The second-type memory block 110b may include the plurality of sub-blocks sBLK1 and sBLK2 stacked in a third direction. In some implementations, the second sub-block sBLK2 may be stacked above the first sub-block sBLK1. For example, the third direction may be a height direction (or Z-axis direction). The third direction may be perpendicular to the first direction and the second direction, but is not limited thereto, and may be modified in various manners.

In some implementations, the plurality of sub-blocks sBLK1 and sBLK2 may be manufactured by processing one wafer. In another example implementation, the plurality of sub-blocks sBLK1 and sBLK2 may be individually manufactured by processing different wafers and then manufactured as a single memory block 110a or 110b through bonding. In other words, the single memory block 110a or 110b may be formed in a cell multi-bonding structure. In some implementations, a plurality of strings within the memory block 110a or 110b may be formed to extend in the third direction, but are not limited thereto, and may be modified and implemented in various directions.

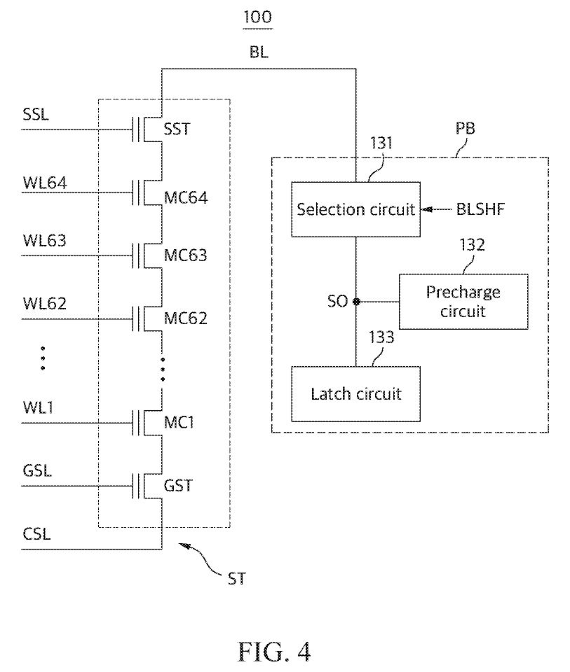

FIG. 4 is a diagram for illustrating an example of a string and an example of a page buffer.

Referring to FIGS. 2 and 4, the memory device 100 according to some implementations may include the memory block 110 including the plurality of sub-blocks sBLK1 and sBLK2 and the page buffer circuit 130 including a plurality of page buffers. Each of the plurality of sub-blocks sBLK1 and sBLK2 may include a plurality of strings. FIG. 4 illustrates a structure in which one string ST within one sub-block sBLK1 or sBLK2 and one page buffer PB within the page buffer circuit 130 are connected through one bit line BL.

One end of the string ST may be connected to the bit line BL, and another end of the string ST may be connected to a common source line CSL. Here, the common source line CSL may be the first common source line CSL1 when a sub-block including the string ST is the first sub-block sBLK1. The common source line CSL may be the second common source line CSL2 when a sub-block including the string ST is the second sub-block sBLK2.

The string ST may include a plurality of memory cells MC1 to MC64 connected to a plurality of word lines WL1 to WL64 and a plurality of selection transistors SST and GST connected to the plurality of special word lines SSL and GSL. Meanwhile, the number of the plurality of memory cells MC1 to MC64 and the number of the plurality of selection transistors SST and GST within one string ST may be modified and implemented in various manners.

In some implementations, each of the plurality of memory cells MC1 to MC64 may include a gate, a source, a drain, and a charge trap layer (CTL). The gate may be connected to one corresponding word line among the plurality of word lines WL1 to WL64, and voltage may be applied to the gate through the corresponding word line. The source and the drain may be a terminal through which a current flows. The CTL may be an insulating layer (for example, a silicon insulating layer) to trap a charge. A threshold voltage of each of the memory cells MC1 to MC64 may vary according to the charge stored in the CTL. Each of the memory cells MC1 to MC64 may store corresponding data based on the threshold voltage. Each of the memory cells MC1 to MC64 may be turned on when a voltage with a level greater than or equal to the threshold voltage is applied to a connected word line and turned off when a voltage with a level less than the threshold voltage is applied. Meanwhile, the CTL may be changed and implemented as a floating gate.

In some implementations, each of the plurality of selection transistors SST and GST may be connected to one of the plurality of special word lines SSL and GSL. Each of the plurality of selection transistors SST and GST may be connected to one of both ends of the plurality of memory cells MC1 to MC64.

For example, a first selection transistor SST may be connected between the bit line BL and a 64th memory cell MC64 adjacent among the plurality of memory cells MC1 to MC64, and a gate of the first selection transistor SST may be connected to a first special word line SSL. The first selection transistor SST may become a turn-on or turn-off state according to a voltage applied to the first special word line SSL, and the first selection transistor SST may switch a connection between the bit line BL and the 64th memory cell MC64 according to the turn-on or turn-off state.

For example, a second selection transistor GST may be connected between the common source line CSL and a first memory cell MC1 adjacent among the plurality of memory cells MC1 to MC64, and a gate of the second selection transistor GST may be connected to a second special word line GSL. The second selection transistor GST may become a turn-on or turn-off state according to a voltage applied to the second special word line GSL, and the second selection transistor GST may switch a connection between the common source line CSL and the first memory cell MC1 according to the turn-on or turn-off state.

In some implementations, the page buffer PB may be connected to the string ST through the bit line BL. The page buffer PB may include a selection circuit 131, a precharge circuit 132, and a latch circuit 133.

The selection circuit 131 may be connected between the bit line BL and a sensing node SO. The selection circuit 131 may, in response to a bit line control voltage BLSHF, switch a connection between the bit line BL and the sensing node SO.

In some implementations, the selection circuit 131 may include a switch transistor. When the bit line control voltage BLSHF is applied to a gate of the switch transistor, the switch transistor may be turned on or turned off according to a level of the bit line control voltage BLSHF. When the switch transistor is turned on, the bit line BL and the sensing node SO may be connected, and when the switch transistor is turned off, the connection between the bit line BL and the sensing node SO may be blocked. The selection circuit 131 may apply a precharge voltage to the bit line BL during a precharge operation and transfer a voltage of the bit line BL based on the threshold voltage of a memory cell to the sensing node SO during a detection operation.

The precharge circuit 132 may precharge the sensing node SO. The precharge circuit 132 may form an initial state for data detection by pre-charging the sensing node SO.

In some implementations, the precharge circuit 132 may include a transistor, which is turned on or turned off in response to a precharge control voltage. For example, during the precharge operation, the precharge control voltage of a first level may be applied to a gate of the transistor, and the transistor may be turned on. In this case, a bias voltage (for example, a source voltage) may be supplied to the sensing node SO through the transistor, and a level of a voltage of the sensing node SO may increase according to the bias voltage. During the detection operation, the precharge control voltage of a second level may be applied to the gate of the transistor, and the transistor may be turned off. In this case, the bias voltage supplied to the sensing node SO through the transistor may be blocked, and the level of the voltage of the sensing node SO may decrease according to a current flow of the bit line BL.

In some implementations, a level of the bit line control voltage BLSHF inputted to the selection circuit 131 of the page buffer PB connected to the first sub-block sBLK1 may be identical a level of the bit line control voltage BLSHF inputted to the selection circuit 131 of the page buffer PB connected to the second sub-block sBLK2. Hereinafter, the page buffer PB connected to the first sub-block sBLK1 is referred to as a first page buffer, and the page buffer PB connected to the second sub-block sBLK2 is referred to as a second page buffer. Meanwhile, levels of the bit line control voltage BLSHF inputted to the first page buffer and the second page buffer may be modified and implemented to be different from each other.

In some implementations, a level of the precharge voltage applied to the bit line BL during the precharge operation may correspond to a level of the bit line control voltage BLSHF inputted to the page buffer PB. For example, as the level of the bit line control voltage BLSHF is higher, the level of the precharge voltage may be higher, and as the level of the bit line control voltage BLSHF is lower, the level of the precharge voltage may be lower. When the levels of the bit line control voltage BLSHF inputted to the first page buffer and the second page buffer are identical, the precharge voltage having an identical level may be applied to a first bit line connected to the first page buffer and a second bit line connected to the second page buffer.

The latch circuit 133 may store data based on the level of the voltage of the sensing node SO. In some implementations, the latch circuit 133 may include a flip-flop in which data is stored, a reset transistor that resets the data of the flip-flop according to a reset signal, and a set transistor that stores the data based on the level of the voltage of the sensing node SO in the flip-flop according to a set signal.

In some implementations, when a level difference is present between the voltage of the bit line BL and a voltage of the common source line CSL during the detection operation, a current may flow through the string ST when the plurality of memory cells MC1 to MC64 and the plurality of selection transistors SST and GST within the string ST are turned on. In this case, as a level difference between the precharge voltage of the bit line BL and the voltage of the common source line CSL increases, a level of the current flowing through the string ST may increase, and the voltage of the sensing node SO connected to the bit line BL may rapidly decrease. Meanwhile, when the precharge voltage of the bit line BL and the voltage of the common source line CSL have an identical level, no current may flow through the string ST.

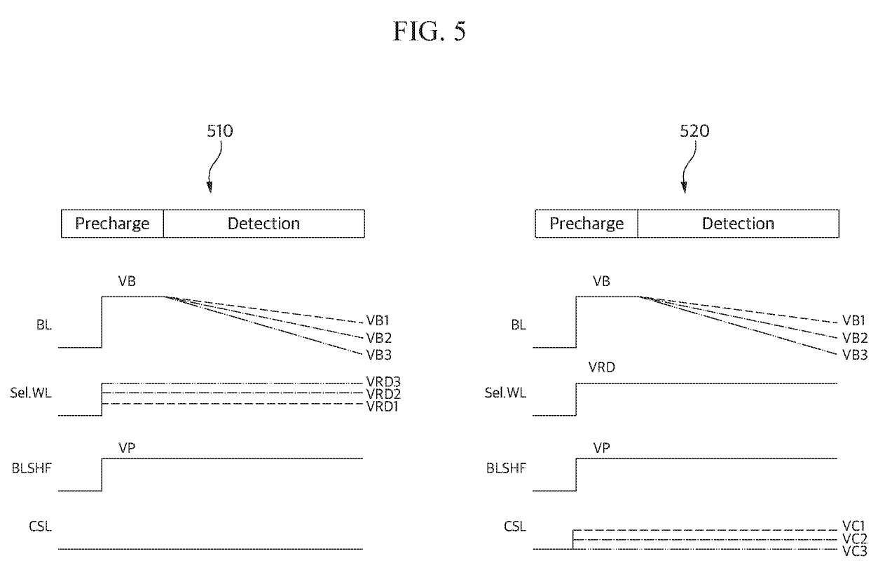

FIG. 5 is a diagram for illustrating an example of a sensing operation.

Referring to FIGS. 4 and 5, each of a first sensing operation 510 and a second sensing operation 520 according to some implementations may include a precharge operation and a detection operation. The first sensing operation 510 may represent a first type of sensing operation, and the second sensing operation 520 may represent a second type of sensing operation. For example, the precharge operation may be performed to set the sensing node SO (or the bit line BL) an initial state (or a reset state). The detection operation may be performed to sense (or identify) the data (or the threshold voltage state) of a memory cell.

In some implementations, during the precharge operation of the first sensing operation 510, the precharge circuit 132 of the page buffer PB may supply a bias voltage to the sensing node SO. In addition, the bit line control voltage BLSHF having a level VP for connecting the bit line BL and the sensing node SO may be inputted to the selection circuit 131 of the page buffer PB. In this case, a precharge voltage VB having a level based on the bit line control voltage BLSHF may be applied to the bit line BL connected to the page buffer PB. Further, a source line voltage (for example, a ground voltage) may be applied to the common source line CSL. One of a plurality of target voltages VRD1 to VRD3 may be applied to a selected word line Sel.WL among the plurality of word lines WL1 to WL64, and a pass voltage for turning on a plurality of unselected memory cells may be applied to a plurality of unselected word lines. A turn-on voltage for turning on the plurality of selection transistors SST and GST may be applied to the plurality of special word lines SSL and GSL. The source line voltage may be applied by the source line driver 150 according to a control signal of the control logic 120. A target voltage VRD, the pass voltage, and the turn-on voltage may be applied by the address decoder 140 according to a control signal of the control logic 120.

In some implementations, during the detection operation of the first sensing operation 510, the precharge circuit 132 of the page buffer PB may block the supply of the bias voltage to the sensing node SO. In this case, a level of a voltage of the bit line BL may decrease according to a current flowing through the string ST.

In some implementations, during the precharge operation of the second sensing operation 520, the precharge circuit 132 of the page buffer PB may supply the bias voltage to the sensing node SO. In addition, the bit line control voltage BLSHF having the level VP for connecting the bit line BL and the sensing node SO may be inputted to the selection circuit 131 of the page buffer PB. In this case, the precharge voltage VB having the level based on the bit line control voltage BLSHF may be applied to the bit line BL connected to the page buffer PB. In addition, one of a plurality of source line voltages VC1 to VC3 may be applied to the common source line CSL. The target voltage VRD may be applied to the selected word line Sel.WL among the plurality of word lines WL1 to WL64, and the pass voltage for turning on the plurality of unselected memory cells may be applied to the plurality of unselected word lines. The turn-on voltage for turning on the plurality of selection transistors SST and GST may be applied to the plurality of special word lines SSL and GSL. The source line voltage may be applied by the source line driver 150 according to a control signal of the control logic 120. The target voltage VRD, the pass voltage, and the turn-on voltage may be applied by the address decoder 140 according to a control signal of the control logic 120.

In some implementations, during the detection operation of the second sensing operation 520, the precharge circuit 132 of the page buffer PB may block the supply of the bias voltage to the sensing node SO. In this case, the level of the voltage of the bit line BL may decrease according to the current flowing through the string ST.

In some implementations, a level of the current flowing through the string ST may vary according to a level difference between voltages of the bit line BL and the common source line CSL and a level difference between a voltage applied to the selected word line Sel.WL and a threshold voltage of a selected memory cell. A degree of a decrease in a level of a voltage of the bit line BL (or the sensing node SO) may vary according to the level of the current. For example, the selected memory cell may operate as a variable resistance, and a resistance value may vary according to the level difference between the voltage applied to the selected word line Sel.WL and the threshold voltage of the selected memory cell. The level of the current may be determined based on the level difference between the voltages of the bit line BL and the common source line CSL and the resistance value.

For example, in the first sensing operation 510, among the plurality of target voltages VRD1 to VRD3 applied to the selected word line Sel.WL, a first target voltage VRD1 may have a lowest level, a second target voltage VRD2 may have a middle level, and a third target voltage VRD3 may have a highest level.

Here, when the first target voltage VRD1 with the lowest level is applied to the selected word line Sel.WL, a current having a lowest level may flow through the selected memory cell, and the level of the voltage of the bit line BL may decrease according to a first gradient VB1 with a lowest level. When the second target voltage VRD2 with the middle level is applied to the selected word line Sel.WL, a current having a middle level may flow through the selected memory cell, and the level of the voltage of the bit line BL may decrease according to a second gradient VB2 with a middle level. When the third target voltage VRD3 with the highest level is applied to the selected word line Sel.WL, a current having a highest level may flow through the selected memory cell, and the level of the voltage of the bit line BL may decrease according to a third gradient VB3 with a highest level. Here, the gradient may be an average gradient.

For example, in the second sensing operation 520, among the plurality of source line voltages VC1 to VC3 applied to the common source line CSL, a first source line voltage VC1 may have a highest level, a second source line voltage VC2 may have a middle level, and a third source line voltage VC3 may have a lowest level.

Here, when the first source line voltage VC1 with the highest level is applied to the common source line CSL, a current having a lowest level may flow through the selected memory cell, and the level of the voltage of the bit line BL may decrease according to the first gradient VB1 with the lowest level. When the second source line voltage VC2 with the middle level is applied to the common source line CSL, a current having a middle level may flow through the selected memory cell, and the level of the voltage of the bit line BL may decrease according to the second gradient VB2 with the middle level. When the third source line voltage VC3 with the lowest level is applied to the common source line CSL, a current having a highest level may flow through the selected memory cell, and the level of the voltage of the bit line BL may decrease according to the third gradient VB3 with the highest level. Here, the gradient may be an average gradient.

In some implementations, the control logic 120 may store table information including corresponding relationships between a precharge voltage of the bit line BL, a voltage of the common source line CSL, a target voltage applied to the selected word line Sel.WL, and a threshold voltage. When sensing a specific threshold voltage, the control logic 120 may determine a level of the voltage of the common source line CSL based on the table information.

According to some implementations of the present disclosure, while not changing a level of the target voltage VRD applied to the selected word line Sel.WL, a change in a voltage of the bit line BL or the sensing node SO may be adjusted by adjusting the level of the voltage of the common source line CSL. In other words, by adjusting the level of the voltage of the common source line CSL, a technical effect of changing a valid target voltage VRD may be obtained. Accordingly, by adjusting the level of the voltage of the common source line CSL, a technical effect of sensing threshold voltages with different levels may be obtained. In addition, according to some implementations of the present disclosure, voltages of the common source line CSL connected to each sub-block may be individually adjusted. When levels of the voltages of the common source line CSL connected to each sub-block are differently adjusted, a technical effect of sensing threshold voltages with different levels for each sub-block may be obtained.

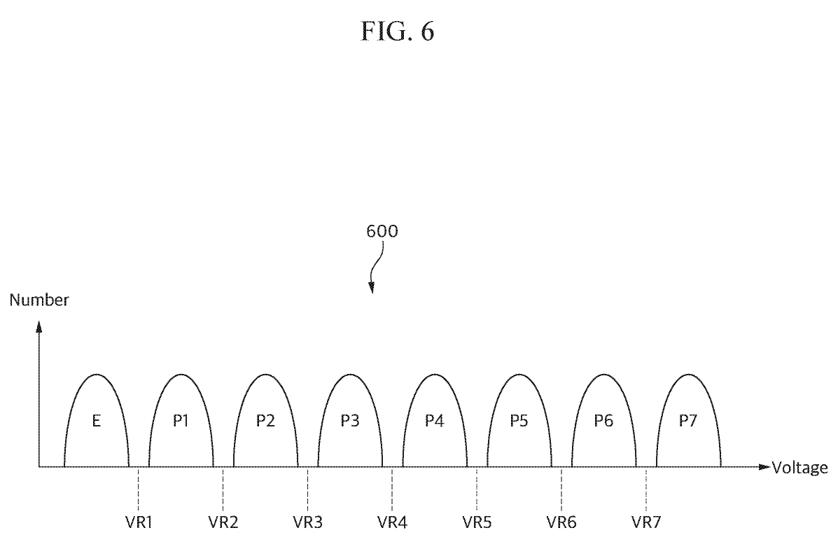

FIG. 6 is a diagram for illustrating an example of a threshold voltage distribution of memory cells.

Referring to FIG. 6, each of a plurality of memory cells may store data. The memory cell may have one state corresponding to data among a plurality of states according to a threshold voltage. The plurality of states may be two states in a SLC manner, four states in an MLC manner, and eight states in a TLC manner. For example, a first distribution 600 of FIG. 6 represents that a plurality of memory cells connected to one word line are programmed to have one of the eight states differentiated from each other based on the TLC manner.

The plurality of states may include an erase state E and a plurality of program states P1 to P7. For example, a memory cell for which an erase operation is performed may have the erase state E. The memory cell may maintain the erase state E or may be programmed to have a program state corresponding to data from the erase state E according to a program operation.

In this case, to sense a state (or data) of the memory cell, a plurality of target voltages VR1 to VR7 may be required. The plurality of target voltages VR1 to VR7 may be a voltage set to differentiate between two adjacent states. In the TLC manner, the number of the plurality of target voltages VR1 to VR7 may be 7.

For example, by changing a level of a voltage applied to a word line seven times, the state (or data) of the memory cell may be sensed. According to some implementations of the present disclosure, by changing a level of a voltage applied to a common source line while maintaining a level of a voltage applied to a word line during a sensing operation (for example, a main sensing operation), the state (or data) of the memory cell may be sensed. In some implementations, by applying voltages of different levels to common source lines for each sub-block, different states may be identified. For example, during the sensing operation, the control logic 120 may apply a first source line voltage corresponding to a first target voltage VR1 for differentiating between the erase state E and a first program state P1 to the first common source line CSL1 connected to the first sub-block sBLK1 and apply a second source line voltage corresponding to a second target voltage VR2 for differentiating between the first program state P1 and a second program state P2 to the second common source line CSL2 connected to the second sub-block sBLK2. Here, a level of the second source line voltage may be lower than a level of the first source line voltage.

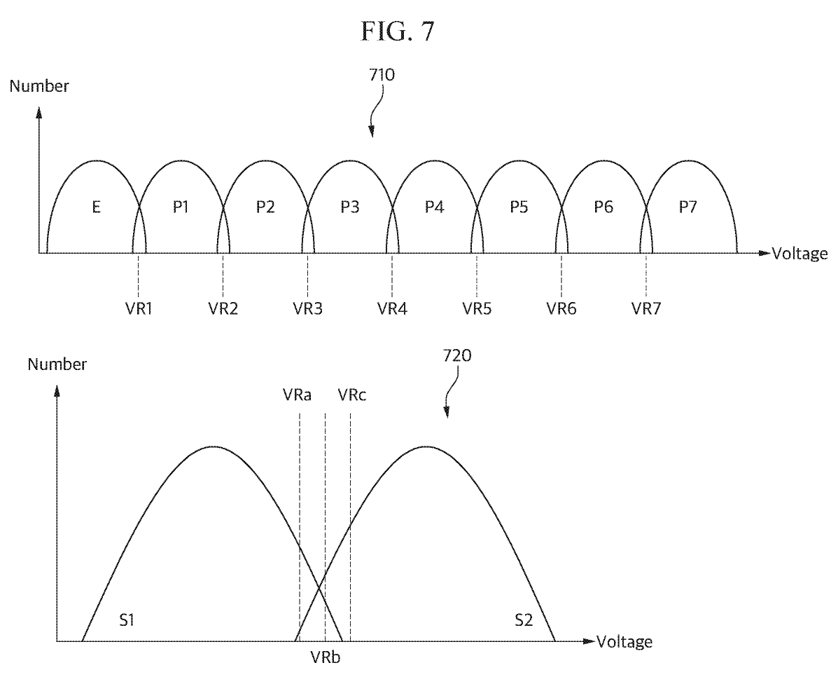

FIG. 7 is a diagram for illustrating an example of a threshold voltage distribution of memory cells and an example of a method of determining an optimum voltage.

Referring to FIGS. 6 and 7, the first distribution 600 and a second distribution 710 represent that a plurality of memory cells connected to one word line are programmed to have one of the eight states differentiated from each other based on the TLC manner. The second distribution 710 represents a state of memory cells degraded after programmed as in the first distribution 600. For example, the degradation may refer to a change in a threshold voltage of a memory cell due to a program operation, a sensing operation, an erase operation, the elapse of time, a temperature, and the like, which occur in or around the memory cell. Since the threshold voltage changes if the degradation occurs in the memory cell, a state (or data) of the memory cell may not be accurately sensed with the plurality of target voltages VR1 to VR7 that are set.

In this case, the memory device 100 may perform a pre-sensing operation prior to a main sensing operation. The memory device 100 may determine an optimum target voltage based on a result of performing the pre-sensing operation and perform the main sensing operation using the optimum target voltage. In some implementations, the pre-sensing operation may include an on-chip valley search (OVS) operation. The OVS operation may be one method for determining the optimal read voltage from the threshold voltage distribution of memory cells. For example, the memory device 100 may sequentially apply a plurality of read voltages to sense the states of the memory cells. The sensed results may be analyzed to identify a valley point (e.g., a minimum point) within the threshold voltage distribution. The memory device 100 may set the voltage corresponding to the identified valley point as the target voltage, so that in a subsequent main sensing operation the target voltage is used to read data. Accordingly, the reliability of data reads can be improved. In other words, even if the threshold voltage distribution of the memory cells changes over time or due to external conditions such as temperature, stable data reads can still be achieved.

Hereinafter, it is assumed and described that the pre-sensing operation is performed for the first sub-block sBLK1 and the second sub-block sBLK2 included in the memory block 110 when two states S1 and S2 overlap. The pre-sensing operation may include a precharge operation and a detection operation.

In some implementations, during the precharge operation, the control logic 120 may control the address decoder 140 to apply a target voltage to a selected word line connected to the first sub-block sBLK1 and the second sub-block sBLK2 and apply a pass voltage to an unselected word line. In some implementations, the control logic 120 may control the plurality of first page buffers PBG1 to apply a precharge voltage to the plurality of first bit lines BL1 to BLk connected to the first sub-block sBLK1 and control the plurality of second page buffers PBG2 to apply a precharge voltage to the plurality of second bit lines BLk+1 to BLm connected to the second sub-block sBLK2.

The control logic 120 may control the source line driver 150 to apply a first voltage to the first common source line CSL1 and apply a second voltage having a lower level than the first voltage to the second common source line CSL2, while the target voltage is applied to the selected word line. In some implementations, the first voltage may be a voltage for identifying a selected memory cell having a threshold voltage greater than or equal to a first level VRa. The second voltage may be a voltage for identifying a selected memory cell having a threshold voltage less than a second level VRb higher than the first level VRa.

In some implementations, the target voltage applied to the selected word line may be maintained. The control logic 120 may control the source line driver 150 to apply the second voltage to the first common source line CSL1 and apply a third voltage having a lower level than the second voltage to the second common source line CSL2, while the target voltage is applied to the selected word line. In some implementations, the second voltage may be a voltage for identifying a selected memory cell having a threshold voltage greater than or equal to the second level VRb. The third voltage may be a voltage for identifying a selected memory cell having a threshold voltage less than a third level VRc higher than the second level VRb.

During the detection operation, the plurality of first page buffers PBG1 may sense and store data of a plurality of selected memory cells of the first sub-block sBLK1 connected to the selected word line through the plurality of first bit lines BL1 to BLk. The plurality of second page buffers PBG2 may sense and store data of a plurality of selected memory cells of the second sub-block sBLK2 connected to the selected word line through the plurality of second bit lines BLk+1 to BLm.

In some implementations, the cell counter 160 may, through the plurality of first page buffers PBG1, identify a first number of a selected memory cell having a threshold voltage greater than or equal to the first level VRa and less than the second level VRb among the plurality of selected memory cells of the first sub-block sBLK1 connected to the selected word line.

For example, the cell counter 160 may count a value (for example, 0 or 1) of data outputted from each of the plurality of first page buffers PBG1. For example, the sensed data of a selected memory cell having a threshold voltage less than the first level VRa may have a first value, and the sensed data of a selected memory cell having a threshold voltage greater than or equal to the first level VRa may have a second value. In this case, the cell counter 160 may identify the number of the selected memory cell having the threshold voltage greater than or equal to the first level VRa by counting the number of the second value outputted from each of the plurality of first page buffers PBG1. In the same manner, the cell counter 160 may identify the number of a selected memory cell having a threshold voltage less than the second level VRb by counting the value of data outputted from each of the plurality of first page buffers PBG1. The cell counter 160 may identify a difference value between the number of the selected memory cell having the threshold voltage less than the second level and the number of the selected memory cell having the threshold voltage greater than or equal to the first level as the first number. Meanwhile, this is merely an example implementation, and an operation for the difference value may be modified to be performed in the control logic 120. In addition, a manner of counting the number of selected memory cells may be modified and implemented in various manners.

In some implementations, the cell counter 160 may, through the plurality of second page buffers PBG2, identify a second number of a selected memory cell having a threshold voltage greater than or equal to the second level VRb and less than the third level VRc among the plurality of selected memory cells of the second sub-block sBLK2 connected to the selected word line. The cell counter 160 may identify the second number in the same manner as the above description.

In some implementations, the control logic 120 may determine levels of voltages applied to the first common source line CSL1 and the second common source line CSL2 during the main sensing operation based on the first number and the second number of the cell counter 160. In another example implementation, the control logic 120 may determine a level of the target voltage applied to the selected word line during the main sensing operation based on the first number and the second number of the cell counter 160.

For example, based on the number of memory cells for each threshold voltage interval including the first number and the second number of the cell counter 160, the control logic 120 may calculate a probability density function based on threshold voltages. The control logic 120 may select a specific point according to a value of the probability density function to calculate a level of an optimum voltage. Here, the specific point may be a point where the number of memory cells with overlapping threshold voltages is minimized. In some implementations, the control logic 120 may, when the optimum voltage is determined, perform the main sensing operation by controlling a voltage corresponding to the level of the optimum voltage to be applied to the first common source line CSL1 and the second common source line CSL2. In another example implementation, the control logic 120 may, when the optimum voltage is determined, perform the main sensing operation by controlling a target voltage corresponding to the level of the optimum voltage to be applied to the selected word line. Meanwhile, threshold voltage intervals are two in the example implementations described above, but are not limited thereto, and may be modified to three or more and implemented.

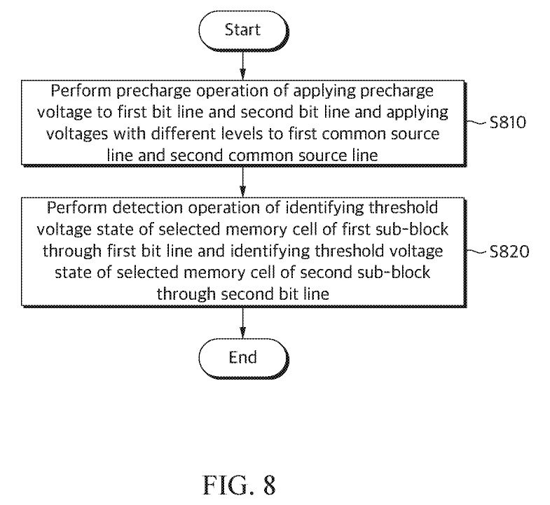

FIG. 8 is a diagram for illustrating an example of an operation method of a memory device.

Referring to FIGS. 2 and 8, the operation method of the memory device 100 according to some implementations may include a plurality of operations S810 and S820. In the operation S810, a precharge operation of applying a precharge voltage to the plurality of first bit lines BL1 to BLk and the plurality of second bit lines BLk+1 to BLm and applying voltages with different levels to the first common source line CSL1 and the second common source line CSL2 may be performed. In the operation S820, while a target voltage is applied to a selected word line among the plurality of word lines WL1 to WLn, a detection operation of identifying threshold voltage states of a plurality of selected memory cells of the first sub-block sBLK1 connected to the selected word line through the plurality of first bit lines BL1 to BLk and identifying threshold voltage states of a plurality of selected memory cells of the second sub-block sBLK2 connected to the selected word line through the plurality of second bit lines BLk+1 to BLm may be performed. The plurality of operations S810 and S820 may be performed to sense the first sub-block sBLK1 and the second sub-block sBLK2.

In some implementations, a level of a voltage applied to the first common source line CSL1 may be less than a level of a precharge voltage applied to the plurality of first bit lines BL1 to BLk. A level of a voltage applied to the second common source line CSL2 may be less than a level of a precharge voltage applied to the plurality of second bit lines BLk+1 to BLm.

In some implementations, the level of the precharge voltage applied to the plurality of first bit lines BL1 to BLk may be identical to the level of the precharge voltage applied to the plurality of second bit lines BLk+1 to BLm.

The memory device 100 according to the above-described example implementations may include a processor, a memory for storing and executing program data, a permanent storage such as a disk drive, a communication port that communicates with an external device, and a user interface device such as a touch panel, a key, and a button. Methods implemented as software modules or algorithms may be stored in a computer-readable recording medium as computer-readable codes or program instructions executable on the processor. Here, the computer-readable recording medium includes a magnetic storage medium (for example, read-only memory (ROM), random-access memory (RAM), floppy disks, and hard disks) and an optically readable medium (for example, CD-ROM and digital versatile discs (DVDs)). The computer-readable recording medium may be distributed among network-connected computer systems, so that the computer-readable codes may be stored and executed in a distributed manner. The medium may be readable by a computer, stored in a memory, and executed on a processor.

According to some implementations, it is possible to provide a memory device, which performs an efficient sensing operation, and an operation method thereof. According to some implementations, it is possible to provide a memory device, which performs a sensing operation with enhanced performance, and an operation method thereof.

According to some implementations, it is possible to sense different threshold voltage states of a memory cell with no change of a voltage level applied to a word line. According to some implementations, it is possible to sense different threshold voltage states of a memory cell with no change of a voltage level applied to a bit line.

According to some implementations, it is possible to perform a sensing operation for each of sub-blocks connected to separate common source lines.

Effects of example implementations are not limited to those described above, and other effects not mentioned herein may be clearly understood by those skilled in the art from the appended claims.

The example implementations may be represented by functional block elements and various processing steps. The functional blocks may be implemented in any number of hardware and/or software configurations that perform specific functions. For example, an example implementation may adopt integrated circuit configurations, such as memory, processing, logic, and/or look-up table, which may execute various functions by the control of one or more microprocessors or other control devices. Similar to that elements may be implemented as software programming or software elements, the example implementations may be implemented in a programming or scripting language such as C, C++, Java, assembler, etc., including various algorithms implemented as a combination of data structures, processes, routines, or other programming constructs. Functional aspects may be implemented in an algorithm running on one or more processors. Further, the example implementations may adopt the existing art for electronic environment setting, signal processing, and/or data processing. Terms such as "mechanism," "element," "means," and "configuration" may be used broadly and are not limited to mechanical and physical configurations. The terms may include the meaning of a series of routines of software in association with a processor or the like.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination

The above-described example implementations are merely examples, and other example implementations may be implemented within the scope of the claims to be described later.

What is claimed is:

1. A memory device comprising:
a memory block including a first sub-block and a second sub-block, wherein the first sub-block includes a plurality of first memory cells, the plurality of first memory cells are connected to a plurality of word lines, a plurality of first bit lines, and a first common source line, the second sub-block includes a plurality of second memory cells, and the plurality of second memory cells are connected to the plurality of word lines, a plurality of second bit lines, and a second common source line;
a page buffer circuit including a plurality of first page buffers and a plurality of second page buffers, wherein the plurality of first page buffers are connected to the plurality of first bit lines, and the plurality of second page buffers are connected to the plurality of second bit lines; and
a control logic configured to, during a sensing operation for a plurality of memory cells of the first sub-block and the second sub-block, individually control a first voltage applied to the first common source line and a second voltage applied to the second common source line, wherein the plurality of memory cells are connected to a word line among the plurality of word lines.

2. The memory device of claim 1, wherein the first voltage applied to the first common source line is different from the second voltage applied to the second common source line.

3. The memory device of claim 2, wherein the first voltage applied to the first common source line is less than a first precharge voltage applied to the plurality of first bit lines, and
wherein the second voltage applied to the second common source line is less than a second precharge voltage applied to the plurality of second bit lines.

4. The memory device of claim 3, wherein the first precharge voltage applied to the plurality of first bit lines is identical to the second precharge voltage applied to the plurality of second bit lines.

5. The memory device of claim 2, wherein the first voltage applied to the first common source line has a first polarity, and the second voltage applied to the second common source line has a second polarity or is a non-polar voltage, the second polarity being different from the first polarity.

6. The memory device of claim 1, comprising a temperature sensor configured to identify a temperature,
wherein the control logic is configured to correct, based on the temperature identified by the temperature sensor, the first voltage applied to the first common source line and the second voltage applied to the second common source line.

7. The memory device of claim 1, wherein the second sub-block is stacked above the first sub-block.

8. The memory device of claim 1, wherein each of a first page buffer among the plurality of first page buffers and a second page buffer among of the plurality of second page buffers respectively comprises:
a selection circuit configured to switch, based on a bit line control voltage, a connection between a sensing node and a respective bit line among the plurality of first bit lines and the plurality of second bit lines;
a precharge circuit configured to precharge the sensing node; and
a latch circuit configured to store data based on a level of a voltage of the sensing node.

9. The memory device of claim 8, wherein a first bit line control voltage inputted to a first selection circuit of the first page buffer is identical to a second bit line control voltage inputted to a second selection circuit of the second page buffer.

10. The memory device of claim 1, comprising a source line driver configured to apply the first voltage to the first common source line and to apply the second voltage to the second common source line.

11. The memory device of claim 10, wherein the control logic is configured to:
control, based on a target voltage being applied to the word line, the source line driver to apply the first voltage to the first common source line and to apply the second voltage to the second common source line, the second voltage being lower than the first voltage; or
control, based on the target voltage being applied to the word line, the source line driver to apply the second voltage to the first common source line and to apply a third voltage the second common source line, the third voltage being lower than the second voltage.

12. The memory device of claim 11, wherein the control logic is configured to identify, using the first voltage, a first memory cell having a first threshold voltage greater than or equal to a first level,
wherein the control logic is configured to identify, using the second voltage, a second memory cell having a second threshold voltage less than a second level higher than the first level or having a third threshold voltage greater than or equal to the second level, and
wherein the control logic is configured to identify, using the third voltage, a third memory cell having a fourth threshold voltage less than a third level higher than the second level.

13. The memory device of claim 12, comprising a cell counter configured to:
identify, through the plurality of first page buffers, a first number of memory cells among a plurality of memory cells of the first sub-block connected to the word line, each memory cell of the first number of memory cells having a fifth threshold voltage greater than or equal to the first level and less than the second level, and
identify, through the plurality of second page buffers, a second number of memory cells among a plurality of memory cells of the second sub-block connected to the word line, each memory cell of the second number of memory cells having a sixth threshold voltage greater than or equal to the second level and less than the third level.

14. The memory device of claim 13, wherein the control logic is configured to determine, based on the first number of memory cells and the second number of memory cells, a plurality of voltages applied to the first common source line and the second common source line during a main sensing operation.

15. The memory device of claim 13, wherein the control logic is configured to determine, based on the first number of memory cells and the second number of memory cells, the target voltage applied to the word line during a main sensing operation.

16. An operation method of a memory device comprising a memory block including a first sub-block and a second sub-block, the first sub-block including a plurality of first memory cells, the plurality of first memory cells being connected to a plurality of word lines, a plurality of first bit lines, and a first common source line, the second sub-block including a plurality of second memory cells, the plurality of second memory cells being connected to the plurality of word lines, a plurality of second bit lines, and a second common source line, and the operation method comprising:
applying, during a precharge operation, a first precharge voltage to the plurality of first bit lines and a second precharge voltage to the plurality of second bit lines, and applying a first voltage to the first common source line and a second voltage to the second common source line, the first voltage being different from the second voltage; and
identifying, based on a target voltage being applied to a word line among the plurality of word lines and during a detection operation, a plurality of first threshold voltage states of a first plurality of memory cells of the first sub-block connected to the word line through the plurality of first bit lines, and identifying a plurality of second threshold voltage states of a second plurality of memory cells of the second sub-block connected to the word line through the plurality of second bit lines.

17. The operation method of claim 16, wherein a first voltage applied to the first common source line is less than the first precharge voltage applied to the plurality of first bit lines, and
wherein a second voltage applied to the second common source line is less than the second precharge voltage applied to the plurality of second bit lines.

18. The operation method of claim 16, wherein the first precharge voltage applied to the plurality of first bit lines is identical to the second precharge voltage applied to the plurality of second bit lines.

19. A memory device comprising:
a memory block including a plurality of sub-blocks, each sub-block of the plurality of sub-blocks being connected to a common source line of a plurality of common source lines separated from each other;
a page buffer circuit including a plurality of page buffers, each page buffer of the plurality of page buffers being connected to a sub-block of the plurality of sub-blocks through a respective bit line and configured to apply a precharge voltage to the respective bit line based on a bit line control voltage;
a source line driver configured to apply a separate voltage to each common source line of the plurality of common source lines; and
a control logic configured to control, during a sensing operation, the source line driver to adjust the separate voltage applied to each common source line of the plurality of common source lines for the plurality of sub-blocks.

20. The memory device of claim 19, wherein a voltage applied to the common source line of the plurality of common source lines is less than the precharge voltage applied to the respective bit line.
